(19) United States
(12) Patent Application Publication
(10) Pub. No.: US 2024/0213325 A1
(43) Pub. Date: Jun. 27, 2024

(54) PRODUCING STRESS IN NANOSHEET TRANSISTOR CHANNELS

(71) Applicant: International Business Machines Corporation, Armonk, NY (US)

(72) Inventors: Reinaldo Vega, Mahopac, NY (US); Robert Robison, Rexford, NY (US); Mohammad Hasanuzzaman, Niskayuna, NY (US)

(21) Appl. No.: 18/086,303

(22) Filed: Dec. 21, 2022

(51) Int. Cl. H01L 29/10; H01L 27/092; H01L 29/06; H01L 29/08; H01L 29/417; H01L 29/423; H01L 29/66; H01L 29/775

(52) U.S. Cl. CPC H01L 29/1054; H01L 27/092; H01L 29/0673; H01L 29/0847; H01L 29/41733; H01L 29/42392; H01L 29/66439; H01L 29/66545; H01L 29/66553; H01L 29/775

(57) ABSTRACT

A semiconductor device includes a first stacked structure and a second stacked structure disposed on a substrate. The first stacked structure comprises a first plurality of gate structures alternately stacked with a first plurality of channel layers, and the second stacked structure comprises a second plurality of gate structures alternately stacked with a second plurality of channel layers. A first plurality of epitaxial source/drain regions are disposed on sides of the first stacked structure, and a second plurality of epitaxial source/drain regions are disposed on sides of the second stacked structure. A first dielectric layer is disposed between the first stacked structure and the substrate, and between the first plurality of epitaxial source/drain regions and the substrate. A second dielectric layer is disposed between the second stacked structure and the substrate. At least a portion of the second plurality of epitaxial source/drain regions contact the substrate.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide structures that produce stress in nanosheet transistor channels.

In one embodiment, a semiconductor device includes a first stacked structure and a second stacked structure disposed on a substrate. The first stacked structure comprises a first plurality of gate structures alternately stacked with a first plurality of channel layers, and the second stacked structure comprises a second plurality of gate structures alternately stacked with a second plurality of channel layers. A first plurality of epitaxial source/drain regions are disposed on sides of the first stacked structure, and a second plurality of epitaxial source/drain regions are disposed on sides of the second stacked structure. A first dielectric layer is disposed between the first stacked structure and the substrate, and between the first plurality of epitaxial source/drain regions and the substrate. A second dielectric layer is disposed between the second stacked structure and the substrate. At least a portion of the second plurality of epitaxial source/drain regions contact the substrate.

In another embodiment, a semiconductor device includes a first nanosheet structure and a second nanosheet structure disposed on a substrate. The first nanosheet structure comprises a first plurality of stacked channel layers, and the second nanosheet structure comprises a second plurality of stacked channel layers. A first plurality of source/drain regions are disposed on lateral sides of the first nanosheet structure, and a second plurality of source/drain regions are disposed on lateral sides of the second nanosheet structure. A first dielectric layer is disposed between the first nanosheet structure and the substrate, and between the first plurality of source/drain regions and the substrate. A second dielectric layer is disposed between the second nanosheet structure and the substrate. At least a portion of the second plurality of source/drain regions contact the substrate.

In another embodiment, a semiconductor device includes at least two stacked nanosheet transistor structures on a substrate. A first dielectric layer is disposed between a first stacked nanosheet transistor structure of the at least two stacked nanosheet transistor structures and the substrate. A second dielectric layer is disposed between a second stacked nanosheet transistor structure of the at least two stacked nanosheet transistor structures and the substrate. A first plurality of source/drain regions correspond to the first stacked nanosheet transistor structure, wherein the first plurality of source/drain regions is disposed on and separated from the substrate by the first dielectric layer. A second plurality of source/drain regions correspond to the second stacked nanosheet transistor structure, wherein the second plurality of source/drain regions is disposed on and contacts the substrate.

These and other features and advantages of embodiments described herein will become more apparent from the accompanying drawings and the following detailed description.

### BRIEF DESCRIPTION OF THE DRAWINGS

FIG. 1 is a schematic cross-sectional view illustrating formation of a stacked structure of semiconductor nanosheet layers, according to an embodiment of the invention.

FIG. 2 is a schematic cross-sectional view illustrating formation of a dummy gate structure and hardmask/spacer on the stacked structure, according to an embodiment of the invention.

FIG. 3A is a schematic cross-sectional view illustrating patterning of the stacked nanosheet layers, according to an embodiment of the invention.

FIG. 3B is a schematic cross-sectional view illustrating patterning of the stacked nanosheet layers and of a bottom dielectric isolation (BDI) layer, according to an embodiment of the invention.

FIGS. 4A and 4B are schematic cross-sectional views illustrating lateral recessing of silicon germanium (SiGe) nanosheet layers, according to embodiments of the invention.

FIGS. 5A and 5B are schematic cross-sectional views illustrating conformal deposition of inner spacer material, according to embodiments of the invention.

FIGS. 6A and 6B are schematic cross-sectional views illustrating removal of portions of the inner spacer material to form inner spacers, according to embodiments of the invention.

FIGS. 7A and 7B are schematic cross-sectional views illustrating epitaxial growth of source/drain regions, according to embodiments of the invention.

FIGS. 8A and 8B are schematic cross-sectional views illustrating inter-layer dielectric (ILD) formation and dummy gate removal, according to embodiments of the invention.

FIGS. 9A and 9B are schematic cross-sectional views illustrating removal of SiGe nanosheet layers, according to embodiments of the invention.

FIGS. 10A and 10B are schematic cross-sectional views illustrating gate formation, according to embodiments of the invention.

FIGS. 11A and 11B are schematic cross-sectional views illustrating contact formation, according to embodiments of the invention.

FIG. 12 is a schematic cross-sectional view illustrating nanosheet transistor structures with different BDI configurations on a substrate, according to an embodiment of the invention.

FIG. 13 is a schematic cross-sectional view illustrating a nanosheet transistor structure with another BDI configuration, according to an embodiment of the invention.

FIG. 14 is a table depicting channel tensile stress values for different carbon concentrations in carbon doped silicon channels for different BDI configurations, according to an embodiment of the invention.

FIG. 15 is a graph depicting n-type transistor performance versus channel tensile stress, according to an embodiment of the invention.

### DETAILED DESCRIPTION

Illustrative embodiments of the invention may be described herein in the context of illustrative methods for forming structures that produce stress in nanosheet transistor channels, wherein the structures are based on channel material and BDI configuration, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers may be used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation complementary FET (CFET) devices may be used. CFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. CFET structures provide improved track height scaling, leading to structural gains (e.g., such as 30-40% structural gains for different types of devices, such as logic devices, static random-access memory (SRAM) devices, etc.). In CFET structures, n-type and p-type nanowires or nanosheets are stacked on each other, eliminating n-to-p separation bottlenecks and reducing the device area footprint. There is, however, a continued to desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation CFET devices.

Although embodiments of the present invention are discussed in connection with nanosheet stacks, the embodiments of the present invention are not necessarily limited thereto, and may similarly apply to nanowire stacks.

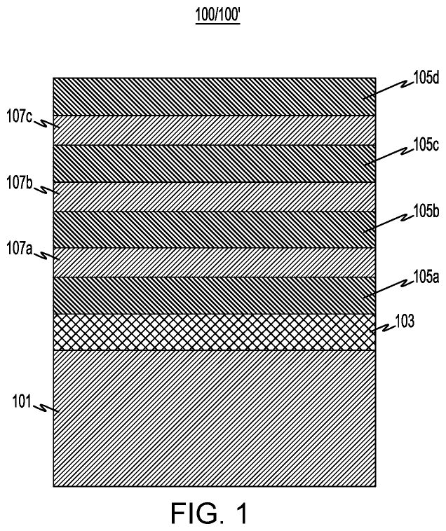

FIG. 1 is a schematic cross-sectional view showing formation of a semiconductor structure 100/100′ including a stacked structure of SiGe and carbon doped silicon (Si:C) nanosheet layers. As explained in more detail herein, SiGe and Si:C are used in the case of an n-type FET (nFET). In the case of a p-type FET, SiGe and silicon (Si) layers are used. The embodiments are discussed in terms of an nFET except where otherwise indicated. Referring to FIG. 1, a semiconductor substrate 101 comprises semiconductor material including, but not limited to, Si, silicon germanium (SiGe), III-V, II-V compound semiconductor or other like semiconductor. In addition, multiple layers of the semiconductor materials can be used as the semiconductor material of the substrate.

In accordance with an embodiment of the present invention, processing may start with a semiconductor-on-insulator structure comprising a bottom dielectric isolation (BDI) layer 103 formed on the semiconductor substrate 101, and first SiGe sacrificial layer 105a formed on the BDI layer 103. The BDI layer 103 may comprise, for example, silicon oxide (SiOₓ) (where x is for example, 2, 1.99 or 2.01), silicon oxycarbide (SiOC), silicon oxycarbonitride (SiOCN) or some other dielectric. Alternatively, if a bulk substrate is used, a sacrificial semiconductor layer between the stacked structure of the SiGe sacrificial layers 105a, 105b, 105c and 105d and Si:C channel layers 107a, 107b and 107c is removed using, for example, an aqueous solution containing ammonium hydroxide (NH₄OH) and hydrogen peroxide (H₂O₂) or a gas containing hydrogen fluoride (HF). Following the removal of the sacrificial semiconductor layer, a dielectric layer is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), followed by an etch back to form the BDI layer 103 on the semiconductor substrate 101.

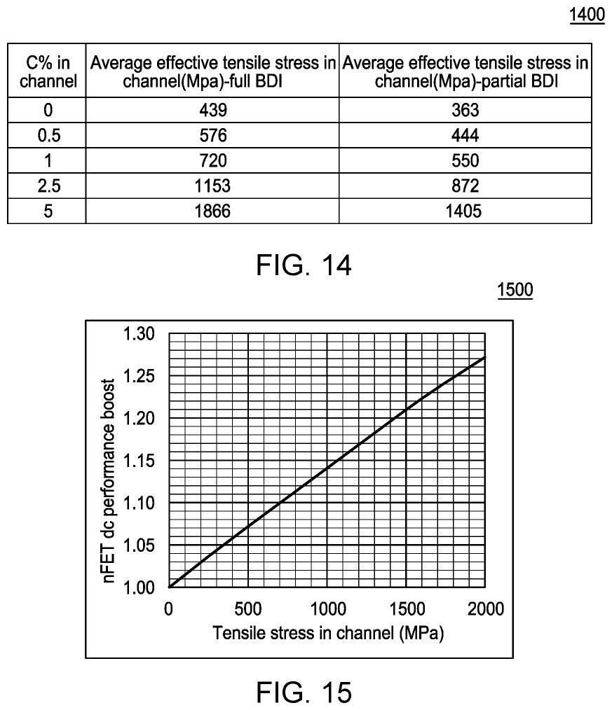

Depending on whether a semiconductor-on-insulator structure or bulk substrate is used, SiGe sacrificial layers 105a, 105b, 105c and 105d and Si:C channel layers 107a, 107b and 107c are epitaxially grown in an alternating and stacked configuration on the sacrificial semiconductor layer, or SiGe sacrificial layers 105b, 105c and 105d and Si:C channel layers 107a, 107b and 107c are epitaxially grown in an alternating and stacked configuration on the first SiGe sacrificial layer 105a. In either case, a first SiGe sacrificial layer 105a is followed by a first Si:C channel layer 107a on the first SiGe sacrificial layer 105a, which is followed by a second SiGe sacrificial layer 105b on the first Si:C channel layer 107a, and so on. As can be understood, the SiGe sacrificial and Si:C channel layers are epitaxially grown from their corresponding underlying semiconductor layers. According to illustrative embodiments, the concentration of carbon in the Si:C channel layers 107a-107c is in the range of about 0.1% to about 10%. As explained in more detail herein in connection with table 1400 in FIG. 14, the average effective tensile stress in an Si:C channel layer 107a-107c increases with increasing carbon concentration.

While four SiGe sacrificial layers 105a-d and three Si:C channel layers 107a-c are shown, the embodiments of the present invention are not necessarily limited to the shown number of sacrificial and channel layers 105, 107, and there may be more or less layers in the same alternating configuration depending on design constraints. The SiGe sacrificial layers 105a-105d are also referred to herein as sacrificial semiconductor layers since, as described further herein, the SiGe sacrificial layers 105a-105d are eventually removed and replaced by gate structures.

Although SiGe is described as a sacrificial material for SiGe sacrificial layers 105a-105d, other materials can be used as long as the sacrificial have the property of being able to be removed selectively compared to the material of the channel layers.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the SiGe sacrificial layers 105a, 105b, 105c and 105d can be in the range of about 6 nm to about 15 nm depending on the application of the device. Also, in a non-limiting illustrative embodiment, Si:C channel layers 107a-107c of the SiGe/Si:C nanosheet stack can be formed on SiGe sacrificial layers 105a-105c by epitaxial growth. In accordance with an embodiment of the present invention, the Si:C layers 107a-107c are epitaxially grown and in-situ doped with carbon at a designated percentage. By “in-situ,” it is meant that the dopant that dictates the conductivity type of the doped layer is introduced during the process step, e.g., epitaxial deposition, which forms the doped layer. In a non-limiting example, a height of the Si:C channel layers 107a-107c can be in the range of about 6 nm to about 15 nm depending on the desired process and application. In accordance with an embodiment of the present invention, each of the Si:C channel layers 107a-107c has the same or substantially the same composition and size as each other, and each of the SiGe sacrificial layers 105a-105d has the same or substantially the same composition and size as each other.

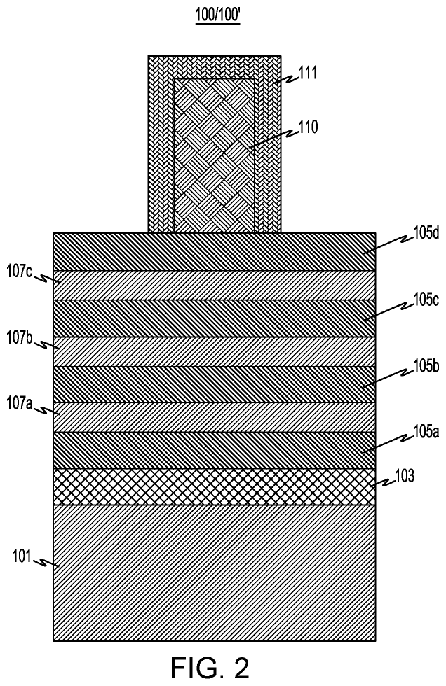

Referring to FIG. 2, a dummy gate structure including a dummy gate portion 110 and hardmask and spacer layers (“hardmask/spacer layer”) 111 is deposited on and around the stacked configuration of SiGe sacrificial layers 105a-105d and Si:C channel layers 107a-107c. The dummy gate portion 110 includes, but is not necessarily limited to, an amorphous silicon (a-Si) layer formed over a thin layer of SiOₓ. The dummy gate portion 110 is deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer.

A hardmask/spacer layer 111 is formed on top of and on sides of the dummy gate portion 110, and can be formed by one or more of the deposition techniques noted in connection with deposition of the dummy gate material. The hardmask and spacer material can comprise for example, one or more dielectrics, including, but not necessarily limited to, silicon nitride (SiN), silicon carbide (SiC), silicon oxynitride (SiON), SiOC, silicon-carbon-nitride (SiCN), boron nitride (BN), silicon boron nitride (SiBN), silicoboron carbonitride (SiBCN), SiOCN, SiOₓ, and combinations thereof. According to an embodiment, the gate hardmask portion is formed on top of the dummy gate portion 110 and spacer portions are formed along lateral sides of the dummy gate portion 110. Hardmask and spacer portions can be the same material, such as, for example, SiN. Alternatively, the hardmask and spacer portions can be different materials, wherein the hardmask portion on top of the dummy gate portion 110 comprises SiN, and the spacer portion on lateral sides of the dummy gate portion 110 comprises SiOCN. For ease of explanation, the hardmask and spacer portions are shown as having the same material in hardmask/spacer layer 111. The hardmask/spacer layer 111 can be formed by any suitable techniques such as deposition followed by directional etching. Deposition may include but is not limited to, ALD or CVD. Directional etching may include but is not limited to, reactive ion etching (RIE).

For ease of the explanation, one dummy gate and hardmask/spacer structure is shown. However, the embodiments are not limited thereto, and multiple dummy gate and hardmask/spacer structures may be formed spaced apart from each other on a stacked structure of SiGe sacrificial layers 105a-105d and Si:C channel layers 107a-107c.

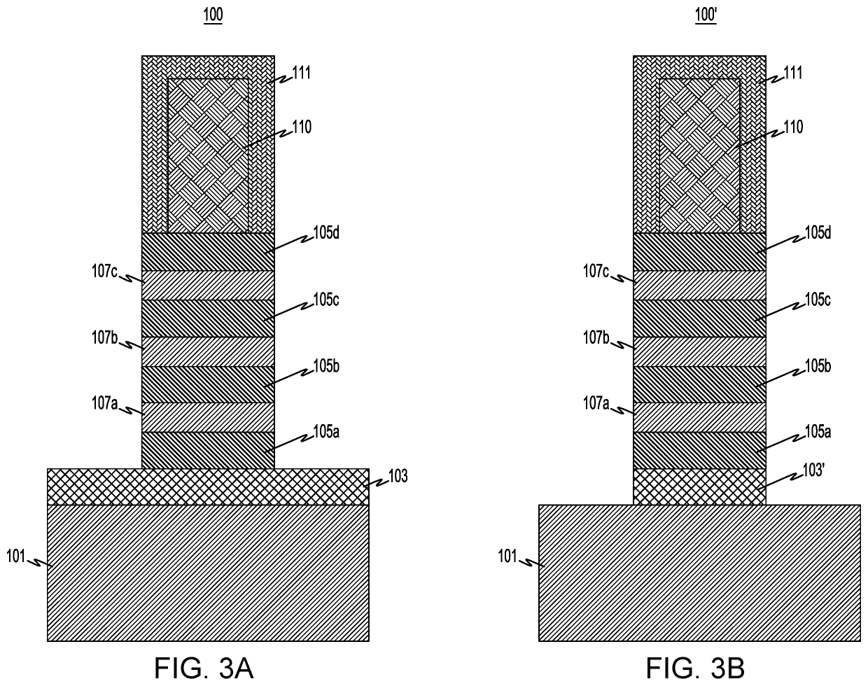

As explained in more detail herein, FIGS. 3A, 4A, 5A, 6A, 7A, 8A, 9A, 10A and 11A illustrate further steps in connection with manufacturing the semiconductor structure 100, and FIGS. 3B, 4B, 5B, 6B, 7B, 8B, 9B, 10B and 11B illustrate further steps in further steps in connection with manufacturing the semiconductor structure 100′. The processing described in connection with FIGS. 3A and 3B follows from FIG. 2. Some of the processes and structures in FIGS. 3A, 4A, 5A, 6A, 7A, 8A, 9A, 10A and 11A are the same as some of the processes and structures in FIGS. 3B, 4B, 5B, 6B, 7B, 8B, 9B, 10B and 11B.

Referring to FIGS. 3A and 3B, exposed portions of the stacked SiGe sacrificial layers 105a-105d and Si:C channel layers 107a-107c, which are not under the hardmask/spacer layer 111 or dummy gate portions 110, are removed using, for example, an etching process, such as RIE, where the hardmask/spacer layer 111 and dummy gate portion 110 are used as a mask. As can be seen in FIGS. 3A and 3B, the portions of the stacked structure of SiGe sacrificial layers 105a-105d and Si:C channel layers 107a-107c under the hardmask/spacer layer 111 and under the dummy gate portion 110 remain after the etching process, and portions of the SiGe sacrificial layers 105a-105d and Si:C channel layers 107a-107c in areas that correspond to where source/drain regions will be formed are removed.

In the semiconductor structure 100 in FIG. 3A, the etching is stopped at the BDI layer 103. Portions of the top surface of the BDI layer 103 on sides of the stacked structure of SiGe sacrificial layers 105a-105d and Si:C channel layers 107a-107c are exposed. Alternatively, in the semiconductor structure 100′ of FIG. 3B, portions of the BDI layer 103 not under the hardmask/spacer layer 111 and dummy gate portion 110 are removed to form a partial BDI layer 103′, such that portions of the top surface of the semiconductor substrate 101 on sides of the stacked structure of SiGe sacrificial layers 105a-105d and Si:C channel layers 107a-107c are exposed. As noted above, for ease of explanation, one dummy gate structure and one patterned nanosheet stack are shown. However, the embodiments are not limited thereto, and more than one dummy gate structure and corresponding patterned nanosheet stack can be formed on a semiconductor substrate 101.

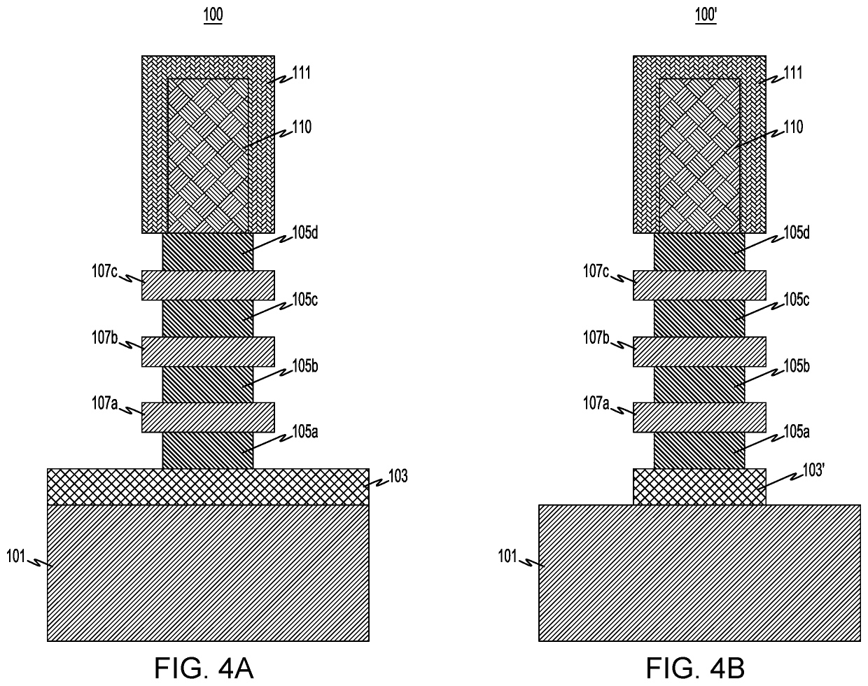

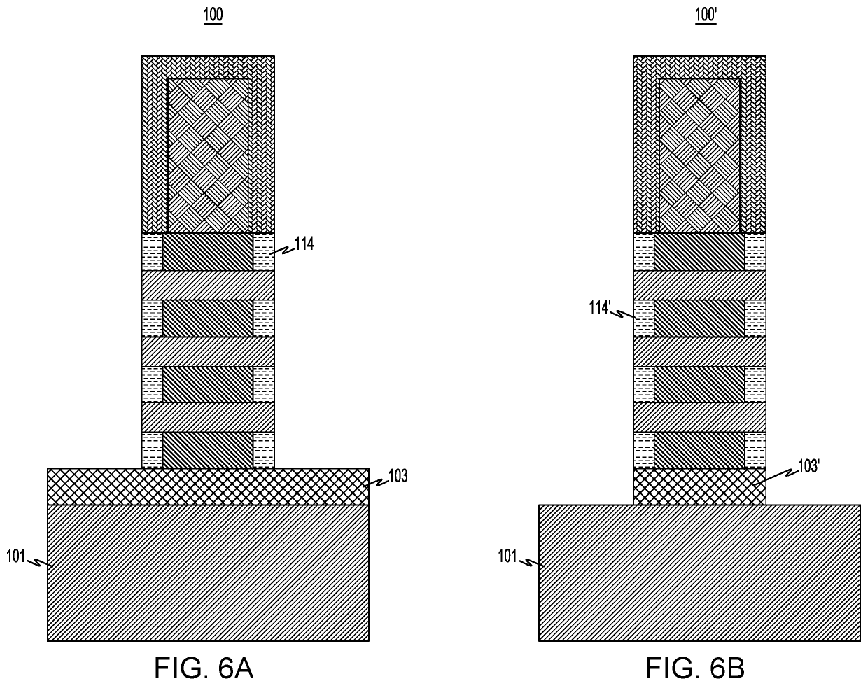

Referring to FIGS. 4A and 4B, due to the germanium in SiGe sacrificial layers 105a-105d, lateral etching of the layers 105a-105d can be performed selective to Si:C channel layers 107a-107c, such that the side portions of the SiGe sacrificial layers 105a-105d can be removed to create vacant areas to be filled in by inner spacers 114 and 114′ (see FIGS. 6A and 6B), while maintaining the side portions of Si:C channel layers 107a-107c. Such etching can be performed using, for example, NH₄+OH:H₂O₂ solution.

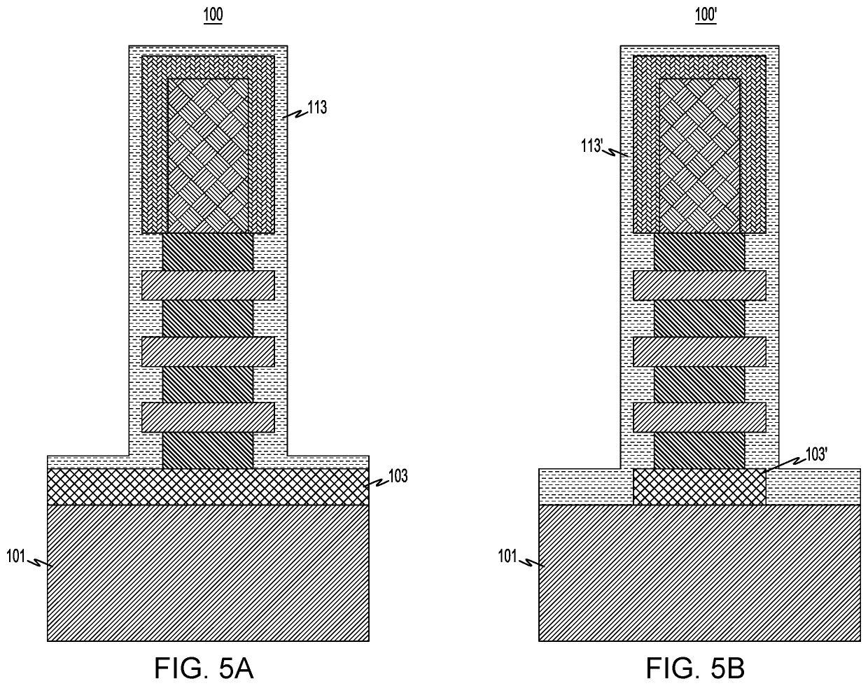

Referring to FIGS. 5A and 5B, inner spacer material 113 and 113′ is conformally deposited on the structures of FIGS. 4A and 4B using a deposition technique such as, for example, ALD or CVD. As can be seen in FIG. 5A, a layer of the inner spacer material 113 is deposited on exposed top and side portions of the hardmask/spacer layer 111, on an exposed portion of the top surface of the BDI layer 103, and on exposed portions of the SiGe sacrificial layers 105a-105d and Si:C channel layers 107a-107c. As can be seen in FIG. 5B, a layer of the inner spacer material 113′ is deposited on exposed top and side portions of the hardmask/spacer layer 111, on an exposed portion of the top surface and side surfaces of the partial BDI layer 103′, on an exposed portion of the top surface of the semiconductor substrate 101 and on exposed portions of the SiGe sacrificial layers 105a-105d and Si:C channel layers 107a-107c. The inner spacer material 113 and 113′ is formed on lateral sides of the SiGe sacrificial layers 105a-d and fills in the vacant portions left by the lateral recessing of the SiGe sacrificial layers 105a-d. In accordance with an embodiment, the inner spacer material 113 and 113′ can comprise a dielectric including, but not necessarily limited to, an oxide, such as SiOₓ, TiOₓ, AlOₓ, etc.

Referring to FIGS. 6A and 6B, portions of the inner spacer material 113 and 113′ are removed to form inner spacers 114 and 114′. According to an embodiment, referring to FIG. 6A, an isotropic etch back process is performed to remove portions of the inner spacer material 113 from top and sides of the hardmask/spacer layer 111, from the top surface of the BDI layer 103, and from side portions of the Si:C channel layers 107a-107c. Referring to FIG. 6B, an isotropic etch back process is performed to remove portions of the inner spacer material 113′ from top and sides of the hardmask/spacer layer 111, from the side surface of the partial BDI layer 103′, from the top surface of the semiconductor substrate 101, and from side portions of the Si:C channel layers 107a-107c. In addition, outer portions of the inner spacer material 113 and 113′ on the lateral sides of the SiGe sacrificial layers 105a-d on top of and below the Si:C channel layers 107a-107c are removed, resulting in the inner spacers 114 and 114′. According to an embodiment, the isotropic etchback process is performed using, for example diluted hydrofluoric acid (DHF). The etch back process selectively removes the inner spacer material 113 and 113′ with respect to the hardmask/spacer layer 111, the BDI layer 103, the partial BDI layer 103′ and the Si:C channel layers 107a-107c.

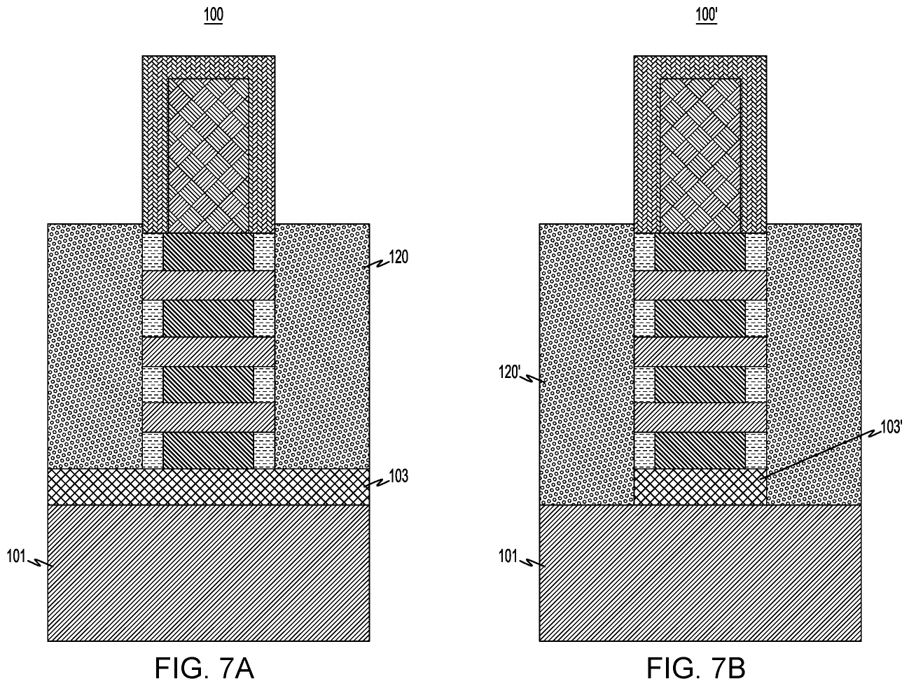

Referring to FIGS. 7A and 7B, epitaxial source/drain regions 120 and 120′ are grown. In the semiconductor structure 100 in FIG. 7A, the epitaxial source/drain regions 120 are grown from and contact exposed sides of the Si:C channel layers 107a-107c of the nanosheet stacks. The BDI layer 103, which covers the top surface of the semiconductor substrate 101, prevents epitaxial growth from the semiconductor substrate 101. In addition, side portions of the SiGe sacrificial layers 105a-105d are covered with the inner spacers 114 during epitaxial growth of epitaxial source/drain regions 120. Due to the inner spacers 114 covering the SiGe sacrificial layers 105a-105d, lateral epitaxial growth does not occur from the SiGe sacrificial layers 105a-105d.

In the semiconductor structure 100′ of FIG. 7B, the epitaxial source/drain regions 120′ are grown from and contact exposed sides of the Si:C channel layers 107a-107c of the nanosheet stacks, and from the exposed top surface of the semiconductor substrate 101 (e.g., silicon) not covered by the partial BDI layer 103′. Side portions of the SiGe sacrificial layers 105a-105d are covered with the inner spacers 114′ during epitaxial growth of epitaxial source/drain regions 120′. Due to the inner spacers 114′ covering the SiGe sacrificial layers 105a-105d, lateral epitaxial growth does not occur from the SiGe sacrificial layers 105a-105d.

According to a non-limiting embodiment of the present invention, the conditions of the epitaxial growth process for the epitaxial source/drain regions 120 and 120′ are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° ° C., and about 5 Torr-about 300 Torr.

After further processing, the epitaxial source/drain regions 120 and 120′ become the source/drain regions for nanosheet transistor devices. For example, in the case of nFETs, the source/drain regions can comprise in-situ phosphorous doped (ISPD) Si or Si:C. In the case of pFETs, where Si channel layers would be used instead of Si:C channel layers 107a-107c in a structure like semiconductor structure 100′ with a partial BDI layer (like partial BDI layer 103′), the source/drain regions can comprise in-situ boron doped (ISBD) SiGe. The epitaxial source/drain regions 120 and 120′ can be doped at concentrations of about 1×10¹⁹/cm³ to about 3×10²¹/cm³. Other doping methods, include, for example, ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI).

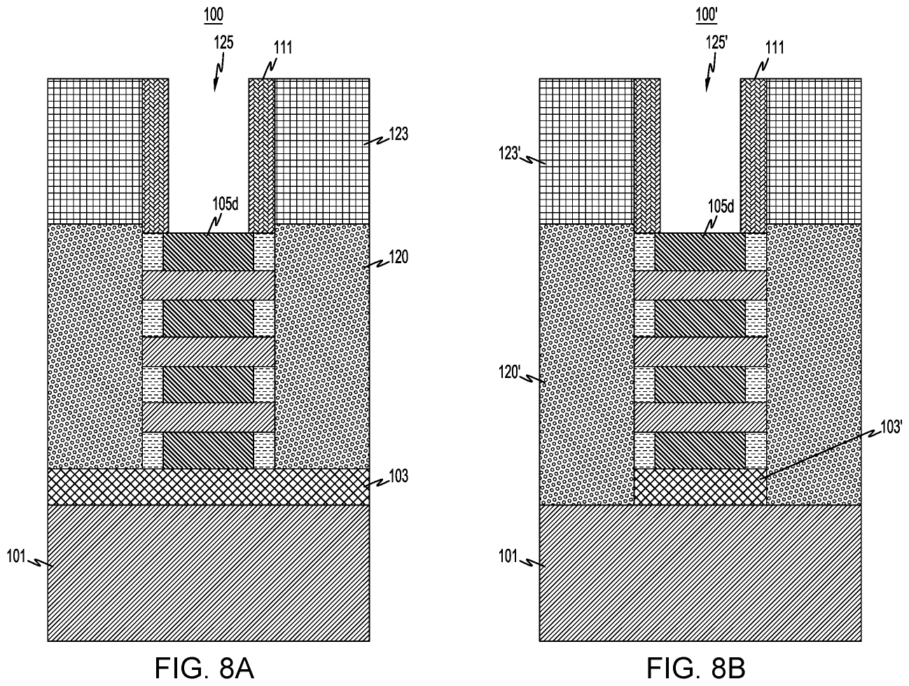

Referring to FIGS. 8A and 8B, the dummy gate portion 110 is selectively removed to create a vacant area 125 or 125′ where a gate structure including gate and dielectric portions will be formed in place of the dummy gate portion 110. The selective removal can be performed using, for example hot ammonia to remove a-Si, and DHF to remove the SiOₓ. Prior to removal of the dummy gate portion 110, an inter-layer dielectric (ILD) layer 123 or 123′ is formed on exposed portions of the epitaxial source/drain regions 120 or 120′, and on sides of the remaining spacer portions of the hardmask/spacer layer 111. The ILD layer 123 or 123′ is deposited using deposition techniques such as, for example, CVD, PECVD, RFCVD, PVD, ALD, MBD, PLD, and/or LSMCD, followed by a planarization process, such as, CMP to remove excess portions of the ILD layer 123 or 123′ deposited on top of the dummy gate portion 110 and remaining spacer portions of the hardmask/spacer layer 111. The ILD layer 123 or 123′ may comprise, for example, SiOₓ, SiOC, SiOCN or some other dielectric.

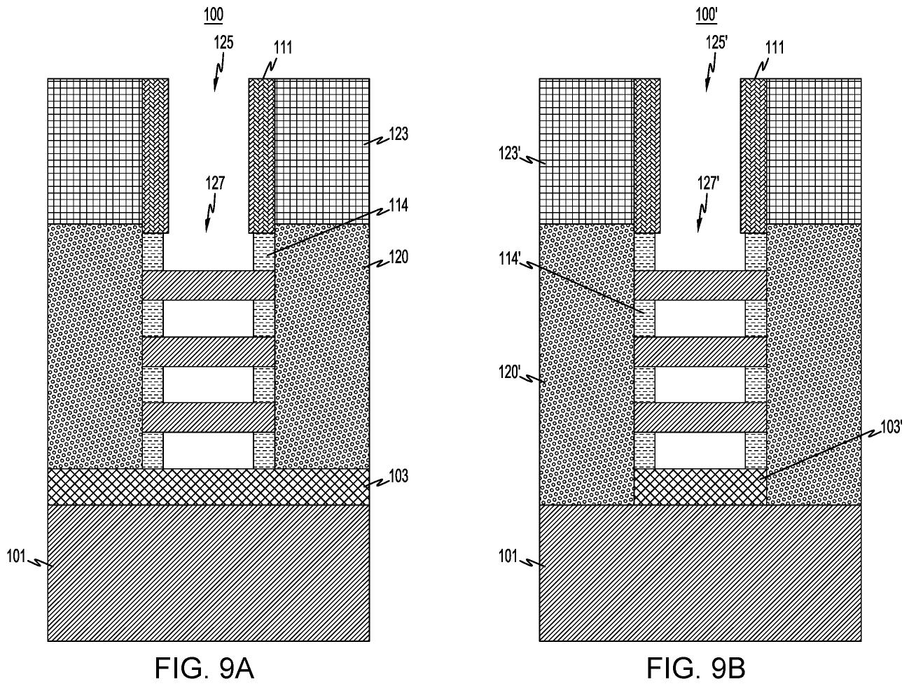

Referring to FIGS. 9A and 9B, the SiGe sacrificial layers 105a-105d are selectively removed to create vacant areas 127 or 127′ where gate and dielectric portions will be formed in place of the SiGe sacrificial layers 105a-105d. The SiGe sacrificial layers 105a-105d are selectively removed with respect to the Si:C channel layers 107a-107c and the hardmask/spacer layers 111 and inner spacers 114/114′. The selective removal can be performed using, for example, a dry HCl etch.

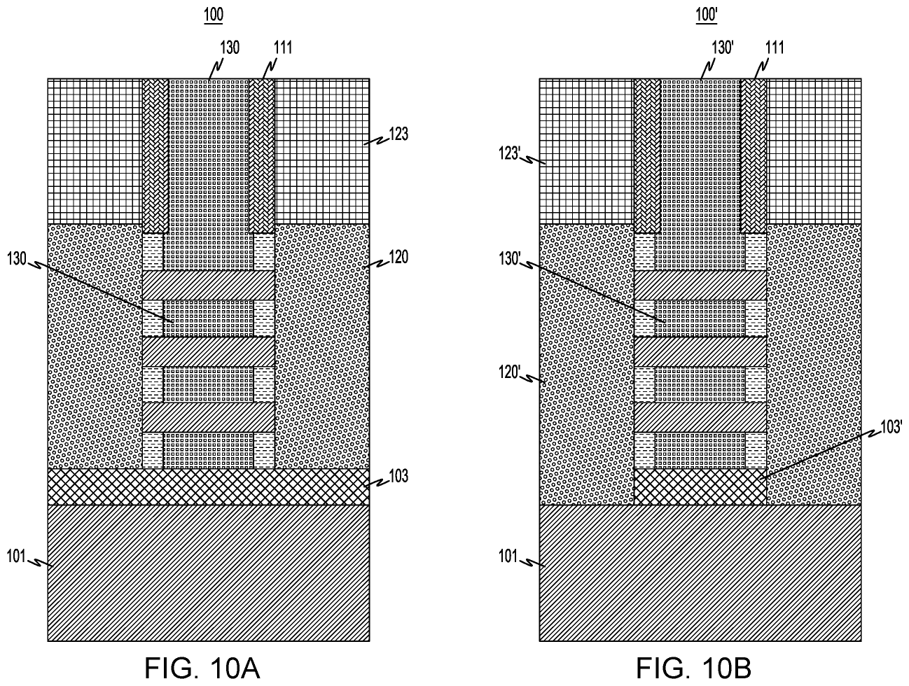

Referring to FIGS. 10A and 10B, the Si:C channel layers 107a-107c are suspended, and gate structures 130/130′, including, for example, gate and dielectric portions are formed in the vacant portions 125/125′ and 127/127′ in place of the removed dummy gate portions 110 and SiGe sacrificial layers 105a-105d. Each gate structure 130/130′ includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 130/130′ each include a gate region including a work-function metal (WFM) layer, including but not necessarily limited to, for a PFET, titanium nitride (TiN), tantalum nitride (TaN) or ruthenium (Ru), and for an NFET, TiN, titanium aluminum nitride (TiAIN), titanium aluminum carbon nitride (TiAICN), titanium aluminum carbide (TiAIC), tantalum aluminum carbide (TaAIC), tantalum aluminum carbon nitride (TaAICN) or lanthanum (La) doped TiN, TaN, which can be deposited on the gate dielectric layer. The gate regions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer.

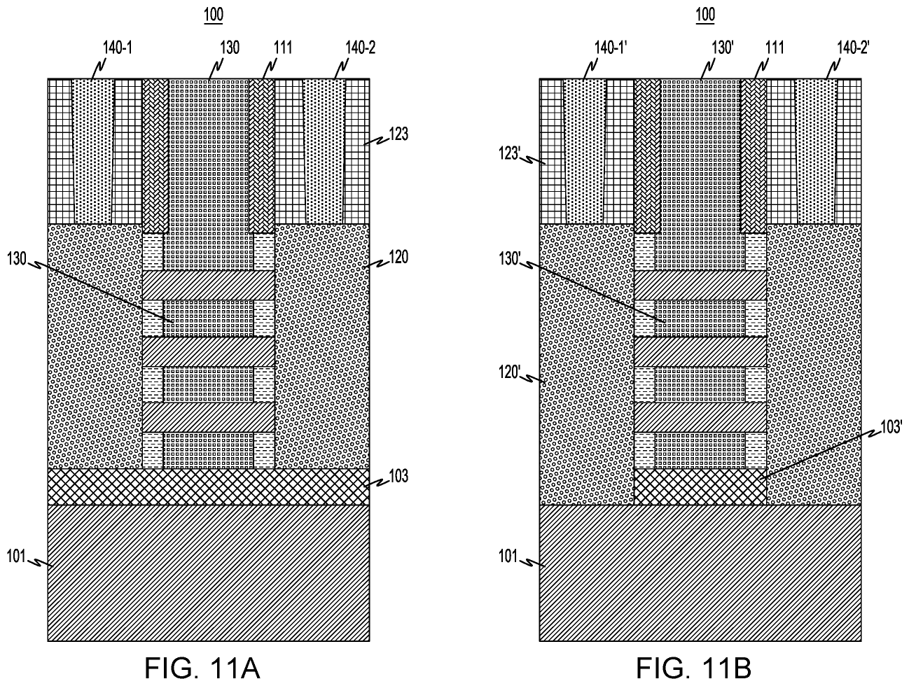

Referring to FIG. 11A, source/drain contacts 140-1 and 140-2 are formed in the ILD layer 123 to contact epitaxial source/drain regions 120. Referring to FIG. 11B, source/drain contacts 140-1′ and 140-2′ are formed in the ILD layer 123′ to contact epitaxial source/drain regions 120′. According to illustrative embodiments, openings corresponding to locations of the source/drain contacts 140-1 and 140-2 are formed in the ILD layer 123, and openings corresponding to locations of the source/drain contacts 140-1′ and 140-2′ are formed in the ILD layer 123′ using, for example, a RIE process. In more detail, portions of the ILD layer 123/123′ exposed via a hardmask (not shown) are etched to form the source/drain contact openings in the ILD layer 123/123′, which are then filled with conductive material (e.g., metal).

The conductive material comprises, for example, a conductor such as, but not necessarily limited to, copper, tungsten, cobalt, ruthenium, etc., and can be deposited in the source/drain contact openings in the ILD layer 123/123′ and other layers using, for example, a deposition technique such as CVD, PECVD, RFCVD, PVD, ALD, MBD, PLD, LSMCD, sputtering and/or plating. Deposition may be followed by a planarization process (e.g., CMP) which planarizes the top surface of the semiconductor structure 100/100′ and removes excess metal material from on top of the ILD layer 123/123′. The source/drain contacts 140-1, 140-2, 140-1′ and 140-2′ can provide, for example, VDD (drain voltage), VSS (source voltage) and ground connections via middle-of-line (MOL) and back-end-of-line (BEOL) metallization layers formed over the source/drain contacts 140-1, 140-2, 140-1′ and 140-2′.

For ease of explanation, one nanosheet/gate structure stack is shown in FIGS. 11A and 11B. However, the embodiments are not limited thereto, and more than one nanosheet/gate structure stack can be formed on a semiconductor substrate 101.

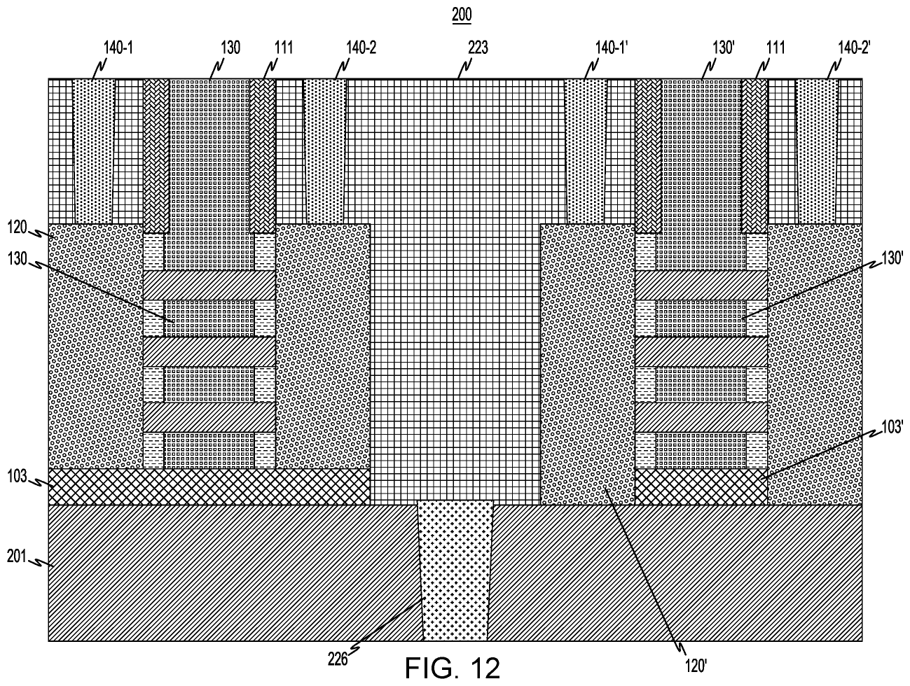

Referring to FIG. 12, in the semiconductor structure 200, the semiconductor structure 100 including the BDI layer 103 and the semiconductor structure 100′ including the partial BDI layer 103′ are formed on the same semiconductor substrate 201, which may comprise the same or a similar material to that of the semiconductor substrate 101. A common ILD layer 223 similar to the ILD layers 123/123′ is formed in the same places as ILD layers 123/123′ and on the semiconductor substrate 201 between the semiconductor structures 100 and 100′. The common ILD layer 223 comprises the same or a similar material to that of the ILD layers 123/123′. In addition, an isolation region 226 (e.g., shallow trench isolation (STI) region) is formed in the semiconductor substrate 201 under the portion of the common ILD layer 223 between the semiconductor structures 100 and 100′. The isolation region 226 comprises a dielectric material the same or similar to that of the ILD layers 123/123′ and 223.

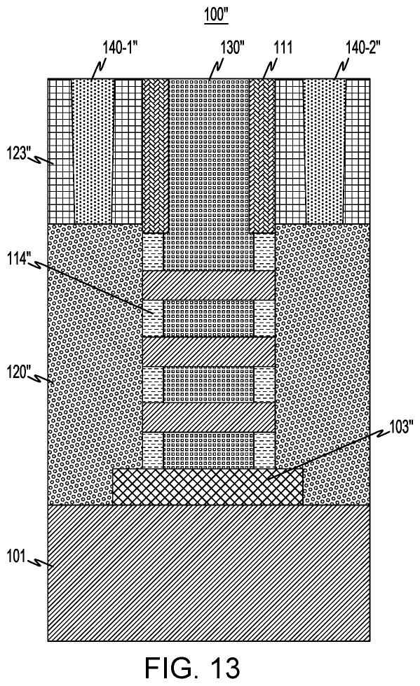

FIG. 13 illustrates a semiconductor structure 100″, which is similar to semiconductor structure 100′, except that a second partial BDI layer 103″ is wider than the partial BDI layer 103′ in that the second partial BDI layer 103″ partly extends beyond sides of the inner spacers 114″. In more detail, first bottom surfaces of respective ones the epitaxial source/drain regions 120″ contact a top surface of the second partial BDI layer 103″, and second bottom surfaces of respective ones the epitaxial source/drain regions 120″ contact a top surface of the semiconductor substrate 101. Other elements such as, for example, ILD layer 123″, gate structures 130″ and source/drain contacts 140-1″ and 140-2″ are the same as or similar to elements having similar numbering discussed hereinabove.

In the semiconductor structures 100 and 200, the BDI layer 103 isolates the epitaxial source/drain regions 120 from the semiconductor substrate 101 or 201, and entire bottom surfaces of the epitaxial source/drain regions 120 are formed on and contact a top surface of the BDI layer 103. In the semiconductor structures 100′, 100″ and 200, portions of respective ones of the epitaxial source/drain regions 120′ or 120″ are formed on respective lateral sides of the partial BDI layer 103′ or second partial BDI layer 103″. Entire bottom surfaces of the epitaxial source/drain regions 120′ contact a top surface of the substrate 101 or 201.

In an illustrative embodiment, channel layers (e.g., Si:C channel layers 107a-107c) of the nanosheet stacks for the semiconductor structures 100 and 100′ on the same semiconductor substrate 201 each comprise carbon doped silicon (e.g., tensile strained Si:C) with a concentration of carbon in a range of about 0.1% to about 10%. In addition, the nanosheet stacks and epitaxial source drain regions 120/120′ for the semiconductor structures 100 and 100′ on the same semiconductor substrate 201 are n-type. Alternatively, the channel layers for the semiconductor structure 100 with the BDI layer 103 on the semiconductor substrate 201 comprise carbon doped silicon and epitaxial source/drain regions 120 for an n-type device, while the channel layers for the semiconductor structure 100′ with the partial BDI layer 103′ on the semiconductor substrate 201 comprise silicon and epitaxial source/drain regions 120′ for a p-type device.

As noted hereinabove, in connection with table 1400 in FIG. 14, the average effective tensile stress in an Si:C channel layer 107a-107c increases with increasing carbon concentration. In addition, referring to the graph 1500 of nFET performance versus channel tensile stress in FIG. 15, nFET performance increases with increasing channel stress. Increases in channel stress cause increases in carrier mobility in the Si:C channel layers 107a-107c.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. An example integrated circuit includes one or more semiconductor devices with the above-described channel, source/drain and BDI layer configurations.

As noted above, illustrative embodiments correspond to methods for forming structures that produce stress in nanosheet transistor channels, wherein the structures are based on channel material and BDI configuration, along with illustrative apparatus, systems and devices formed using such methods. The nFETs of the illustrative embodiments are built with Si:C channels, which enhance tensile stress in the channels, and thus enhance nFET performance. In addition, the partial BDI layers enhance retention of tensile stress in the channel. Advantageously, the embodiments provide nFET performance boosts by increasing channel mobility due to the tensile stress produced in the nanosheet channels.

The embodiments differ from conventional structures used for low leakage and power, where it is difficult to produce tensile strain in channels. The embodiments advantageously incorporate partial BDI structures for nFET and pFET device and/or partial or full BDI structures with Si:C channels for nFET devices to produce channel tensile strain. In addition, the embodiments vary the percentage of carbon in the Si:C channels to cause increases in the tensile strain of the channels.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a first stacked structure disposed on a substrate, wherein the first stacked structure comprises a first plurality of gate structures alternately stacked with a first plurality of channel layers;
a first plurality of epitaxial source/drain regions disposed on sides of the first stacked structure;
a first dielectric layer disposed between the first stacked structure and the substrate, and between the first plurality of epitaxial source/drain regions and the substrate;
a second stacked structure disposed on the substrate, wherein the second stacked structure comprises a second plurality of gate structures alternately stacked with a second plurality of channel layers;
a second plurality of epitaxial source/drain regions disposed on sides of the second stacked structure; and
a second dielectric layer disposed between the second stacked structure and the substrate, wherein at least a portion of the second plurality of epitaxial source/drain regions contact the substrate.

2. The semiconductor device of claim 1, wherein the first dielectric layer isolates the first plurality of epitaxial source/drain regions from the substrate.

3. The semiconductor device of claim 1, wherein portions of respective ones of the second plurality of epitaxial source/drain regions are formed on respective lateral sides of the second dielectric layer.

4. The semiconductor device of claim 1, wherein bottom surfaces of respective ones the first plurality of epitaxial source/drain regions contact a top surface of the first dielectric layer.

5. The semiconductor device of claim 4, wherein bottom surfaces of respective ones the second plurality of epitaxial source/drain regions contact a top surface of the substrate.

6. The semiconductor device of claim 1, wherein the first plurality of channel layers and the second plurality of channel layers each comprise strained carbon doped silicon.

7. The semiconductor device of claim 6, wherein the first plurality of channel layers and the second plurality of channel layers each comprise a concentration of carbon in a range of about 0.1% to about 10%.

8. The semiconductor device of claim 6, wherein the first stacked structure and the second stacked structure, the first plurality of epitaxial source/drain regions and the second plurality of epitaxial source/drain regions correspond to n-type transistors.

9. The semiconductor device of claim 1, wherein:
the first plurality of epitaxial source/drain regions contact sides of the first plurality of channel layers; and
the second plurality of epitaxial source/drain regions contact sides of the second plurality of channel layers.

10. The semiconductor device of claim 1, further comprising:
a first plurality of spacers disposed on lateral sides of the first plurality of gate structures; and
a second plurality of spacers disposed on lateral sides of the second plurality of gate structures.

11. The semiconductor device of claim 1, wherein the first plurality of channel layers comprise carbon doped silicon, and the second plurality of channel layers comprise silicon.

12. The semiconductor device of claim 1, wherein the first stacked structure and the first plurality of epitaxial source/drain regions correspond to an n-type transistor, and the second stacked structure and the second plurality of epitaxial source/drain regions correspond to a p-type transistor.

13. The semiconductor device of claim 1, wherein:
first bottom surfaces of respective ones the second plurality of epitaxial source/drain regions contact a top surface of the second dielectric layer; and
second bottom surfaces of respective ones the second plurality of epitaxial source/drain regions contact a top surface of the substrate.

14. A semiconductor device, comprising:
a first nanosheet structure disposed on a substrate, wherein the first nanosheet structure comprises a first plurality of stacked channel layers;
a first plurality of source/drain regions disposed on lateral sides of the first nanosheet structure;
a first dielectric layer disposed between the first nanosheet structure and the substrate, and between the first plurality of source/drain regions and the substrate;
a second nanosheet structure disposed on the substrate, wherein the second nanosheet structure comprises a second plurality of stacked channel layers;
a second plurality of source/drain regions disposed on lateral sides of the second nanosheet structure; and
a second dielectric layer disposed between the second nanosheet structure and the substrate, wherein at least a portion of the second plurality of source/drain regions contact the substrate.

15. The semiconductor device of claim 14, wherein bottom surfaces of respective ones of the first plurality of source/drain regions contact a top surface of the first dielectric layer.

16. The semiconductor device of claim 15, wherein bottom surfaces of respective ones the second plurality of source/drain regions contact a top surface of the substrate.

17. The semiconductor device of claim 14, wherein the first plurality of stacked channel layers and the second plurality of stacked channel layers each comprise carbon doped silicon.

18. A semiconductor device, comprising:
at least two stacked nanosheet transistor structures on a substrate;
a first dielectric layer disposed between a first stacked nanosheet transistor structure of the at least two stacked nanosheet transistor structures and the substrate;
a second dielectric layer disposed between a second stacked nanosheet transistor structure of the at least two stacked nanosheet transistor structures and the substrate;
a first plurality of source/drain regions corresponding to the first stacked nanosheet transistor structure, wherein the first plurality of source/drain regions is disposed on and separated from the substrate by the first dielectric layer; and
a second plurality of source/drain regions corresponding to the second stacked nanosheet transistor structure, wherein the second plurality of source/drain regions is disposed on and contacts the substrate.

19. The semiconductor device of claim 18, wherein:
the first stacked nanosheet transistor structure comprises a first plurality of channel layers;
the second stacked nanosheet transistor structure comprises a second plurality of channel layers; and
the first plurality of channel layers and the second plurality of channel layers each comprise carbon doped silicon.

20. The semiconductor device of claim 18, wherein the at least two stacked nanosheet transistor structures, the first plurality of source/drain regions and the second plurality of source/drain regions correspond to n-type transistors.
